(19) United States
(12) Patent Application Publication
(10) Pub. No.: US 2026/0343937 A1
(43) Pub. Date: Oct. 29, 2026

(54) SEMICONDUCTOR DEVICE INCLUDING A FIRST TRENCH DIELECTRIC AND A SECOND TRENCH DIELECTRIC

(71) Applicant: Infineon Technologies Dresden AG & Co. KG, Dresden (DE)

(72) Inventor: Andreas Meiser, Sauerlach (DE)

(21) Appl. No.: 19/660,771

(22) Filed: Apr. 28, 2026

(30) Foreign Application Priority Data
Apr. 29, 2025 (DE) 102025116539.4

(51) Int. Cl. H10D 30/65; H10D 30/01; H10D 64/00; H10D 64/27

(52) U.S. Cl. CPC H10D 30/658; H10D 30/0289; H10D 30/655; H10D 64/117; H10D 64/516; H10D 64/518; H10D 64/519

(57) ABSTRACT

A semiconductor device is proposed. The semiconductor device includes a semiconductor body having a first main surface and a second main surface opposite to the first main surface along a vertical direction. The semiconductor device further includes a source and a drain. A trench is arranged between the drain and the source along a first lateral direction. The trench includes a first trench segment and a second trench segment merged into one another along the first lateral direction. A first trench dielectric and a first trench electrode are arranged in the first trench segment. A second trench dielectric and a second trench electrode are arranged in the second trench segment. The second trench electrode is spaced from the first trench electrode along the first lateral direction.

### TECHNICAL FIELD

The present disclosure is related to a semiconductor device, in particular to a semiconductor device including a first trench dielectric and a second trench dielectric.

### BACKGROUND

Technology development of new generations of semiconductor devices for automotive and industrial electronics aims at a low on-state resistance, Rₒₙ, while securing a high voltage blocking capability. For example, a metal oxide semiconductor field effect transistor, MOSFET is typically designed, depending upon application requirements, for blocking drain to source voltages V_{ds} of some tens to some hundreds or thousands of volts. Power MOSFETs typically conduct currents which may be up to some hundreds of Amperes at gate-source voltages of about 2 to 20 V. Lateral power semiconductor transistors, in which a channel current mainly flows parallel to a main surface of a semiconductor body, may be part of integrated circuits including further components, e.g. switches, bridges and control circuits. For example, power transistors such as lateral power MOSFETs may be used in DC/DC or AC/DC converters for switching a current. Converter frequencies may range from 100 kHz up to several MHz, for example. In order to reduce switching losses, attempts are being made to minimize capacitances in the power transistors. Thereby, switching operations may be accelerated.

There may be a desire for improved semiconductor devices including trench dielectrics.

### SUMMARY

An example of the present disclosure relates to s semiconductor device. The semiconductor device includes a semiconductor body having a first main surface and a second main surface opposite to the first main surface along a vertical direction. The semiconductor device further includes a source and a drain. The semiconductor device further includes a trench arranged between the drain and the source along a first lateral direction. The trench includes a first trench segment and a second trench segment merged into one another along the first lateral direction. The semiconductor device further includes a first trench dielectric and a first trench electrode in the first trench segment. The semiconductor device further includes a second trench dielectric and a second trench electrode in the second trench segment. The second trench electrode is spaced from the first trench electrode along the first lateral direction.

An example of the present disclosure relates to a method of manufacturing a semiconductor device. The method includes providing a semiconductor body having a first main surface and a second main surface opposite to the first main surface along a vertical direction. The method further includes forming a source and a drain. The method further includes forming a trench arranged between the drain and the source along a first lateral direction. The trench includes a first trench segment and a second trench segment merged into one another along the first lateral direction. The method further includes forming a first trench dielectric and a first trench electrode in the first trench segment. The method further includes forming a second trench dielectric and a second trench electrode in the second trench segment. The second trench electrode is spaced from the first trench electrode along the first lateral direction.

### BRIEF DESCRIPTION OF THE DRAWINGS

The accompanying drawings are included to provide a further understanding of the embodiments and are incorporated in and constitute a part of this specification. The drawings illustrate examples of semiconductor devices and manufacturing methods and together with the description serve to explain principles of the examples. Further examples are described in the following detailed description and the claims.

FIG. 1A is a schematic top view for illustrating an example of a semiconductor device including first and second trench segments.

FIG. 1B is a schematic cross-sectional view along line AA of the semiconductor device illustrated in FIG. 1A.

FIG. 2A is a schematic top view for illustrating another example of a semiconductor device including first and second trench segments.

FIG. 2B is a schematic cross-sectional view along line AA of the semiconductor device illustrated in FIG. 2A.

FIGS. 3A to 3I are schematic cross-sectional views for illustrating a method of manufacturing a semiconductor device.

### DETAILED DESCRIPTION

In the following detailed description, reference is made to the accompanying drawings, which form a part hereof and in which are shown by way of illustrations specific examples in which semiconductor substrates may be processed. It is to be understood that other examples may be utilized and structural or logical changes may be made without departing from the scope of the present disclosure. For example, features illustrated or described for one example can be used on or in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms "having", "containing", "including", "comprising" and the like are open, and the terms indicate the presence of stated structures, elements or features but do not preclude the presence of additional elements or features. The articles "a", "an" and "the" are intended to include the plural as well as the singular, unless the context clearly indicates otherwise.

The term "electrically connected" describes a permanent low-resistive connection between electrically connected elements, for example a direct contact between the concerned elements or a low-resistive connection via a metal and/or heavily doped semiconductor material. The term "electrically coupled" includes that one or more intervening element(s) adapted for signal and/or power transmission may be connected between the electrically coupled elements, for example, elements that are controllable to temporarily provide a low-resistive connection in a first state and a high-resistive electric decoupling in a second state. An ohmic contact is a non-rectifying electrical junction.

Ranges given for physical dimensions include the boundary values. For example, a range for a parameter y from a to b reads as a ≤ y ≤ b. The same holds for ranges with one boundary value like “at most” and “at least”.

The term "on" is not to be construed as meaning only "directly on". Rather, if one element is positioned "on" or “over” another element (e.g., a layer is "on" or “over” another layer or "on" or “over” a substrate), a further component (e.g., a further layer) may be positioned between the two elements (e.g., a further layer may be positioned between a layer and a substrate if the layer is "on" or “over” said substrate).

An example of the present disclosure relates to a semiconductor device. The semiconductor device may include a semiconductor body having a first main surface and a second main surface opposite to the first main surface along a vertical direction. The semiconductor device may further include a source and a drain. The semiconductor device may further include a trench arranged between the drain and the source along a first lateral direction. The trench may further include a first trench segment and a second trench segment merged into one another along the first lateral direction. The semiconductor device may further include a first trench dielectric and a first trench electrode in the first trench segment. The semiconductor device may further include a second trench dielectric and a second trench electrode in the second trench segment. The second trench electrode may be spaced from the first trench electrode along the first lateral direction.

The semiconductor device may be a lateral power semiconductor device, e.g. a lateral power insulated gate field effect transistor (IGFET) such as a MOSFET, having a load current flow between a first load terminal or first load contact at the first main surface and a second load terminal or a second load contact at the first main surface. The first and second load terminals may be laterally spaced from one another. The lateral power semiconductor device may be configured to conduct currents of more than 1A or more than 10 A or even more than 30 A and may be further configured to block voltages between the first and second load terminals, e.g. between drain and source of a MOSFET, in the range of several tens, or several hundreds of volts. The blocking voltage may correspond to a voltage class specified in a datasheet of the power semiconductor device, for example.

The semiconductor body may include or consist of a semiconductor material from the group IV elemental semiconductors, IV-IV compound semiconductor material, III-V compound semiconductor material, or II-VI compound semiconductor material. Examples of semiconductor materials from the group IV elemental semiconductors include, inter alia, silicon (Si) and germanium (Ge). Examples of IV-IV compound semiconductor materials include, inter alia, silicon carbide (SiC) and silicon germanium (SiGe). Examples of III-V compound semiconductor material include, inter alia, gallium arsenide (GaAs), gallium nitride (GaN), gallium phosphide (GaP), indium phosphide (InP), indium gallium nitride (InGaN) and indium gallium arsenide (InGaAs). Examples of II-VI compound semiconductor materials include, inter alia, cadmium telluride (CdTe), mercury-cadmium-telluride (CdHgTe), and cadmium magnesium telluride (CdMgTe). For example, the semiconductor body may be a Czochralski, CZ (e.g. a MCZ magnetic Czochralski, MCZ), or a float zone (FZ) or an epitaxially deposited silicon semiconductor structure. For example, the semiconductor body may include a semiconductor substrate, e.g. a semiconductor wafer or a die separated from the wafer after wafer dicing, and one or more epitaxial layers deposited thereon. For, example, the one or more epitaxial layers may be arranged between the semiconductor substrate and the first main surface and may differ from the semiconductor substrate with respect to a doping concentration.

For example, the source may include one or more conductive materials, e.g. doped semiconductor material configured to pass the current between a channel region and a source contact over the first main surface or over the second main surface. For example, the source may include a doped source region having a conductivity type equal to a conductivity type of a channel region. For example, the doped source region may be an n⁺-doped region of an n-channel MOSFET or may a p⁺-doped region of a p-channel MOSFET. The source may also include a conductive material in a trench, e.g. a highly doped polycrystalline material or another conductive material. Likewise, the drain may include one or more conductive materials, e.g. doped semiconductor material configured to pass the current between a drift region to a drain contact over the first main surface or over the second main surface. For example, the drain may include a doped region having a conductivity type equal to a conductivity type of a channel region. For example, the doped drain region may be an n⁺-doped region of an n-channel MOSFET or may a p⁺-doped region of a p-channel MOSFET. The drain may also include a conductive material in a trench, e.g. a highly doped polycrystalline material.

For example, the first trench segment and the second trench segment may be merged into one another by the first and second trench dielectrics. Thus, along the first lateral direction, a mesa region may be omitted between the first and second trench segments, and the first trench dielectric may directly adjoin to the second trench dielectric along the first lateral direction.

The first trench electrode and the second trench electrode may be separated along the first lateral direction by a dielectric including the first and/or second trench dielectric, for example.

By merging the first trench segment and the second trench segment along the first lateral direction, a capacitance between the first trench electrode and the drain and a capacitance between the second trench electrode and the drain may be reduced compared with a corresponding drain capacitance in case of a mesa region between the first trench segment and the second trench segment. This may allow for accelerating switching operations, for example.

For example, the second trench electrode may be a gate electrode and the second trench dielectric may be a gate dielectric. A part of the semiconductor body adjoining a sidewall and/or a bottom side of the second trench segment may include a channel region. For example, the channel region may be a part of a body region that adjoins to the sidewall and/or to the bottom side of the second trench segment. In the channel region, a conductivity may be controlled via a voltage applied to the gate electrode. For example, a conductivity in the channel region may be switched between an on- and off-state by field effect controlled via the gate electrode.

For example, a first vertical distance between a bottom of the first trench segment and the first main surface may be greater than a second vertical distance between a bottom of the second trench segment and the first main surface. This may allow for a reduction of the area-specific on-resistance by a further improvement of charge-compensation when using the first trench electrode as a field-plate.

For example, a width of the first trench segment along a second lateral direction may be greater than a width of the second trench segment. The second lateral direction may be perpendicular to the first lateral direction. The width may be an extent of the respective trench segment along the second lateral direction, e.g. an extent at a position in a middle of the respective trench segment at the first main surface.

For example, a thickness of the first trench dielectric may be greater than a thickness of the second trench dielectric. The first thickness may be set depending on a blocking voltage of the semiconductor device, for example.

For example, a distance between the first trench electrode and the second trench electrode along the first lateral direction may be equal to or greater than the thickness of the first trench dielectric.

For example, a width of the first trench electrode may be smaller than a width of the second trench electrode. The width may be an extent of the respective trench electrode along the second lateral direction, e.g. an extent at a position in the middle of the respective trench electrode at the first main surface.

For example, a length of the first trench electrode along the first lateral direction may be greater than a length of the second trench electrode along the first lateral direction. For example, the length of the first trench electrode along the first lateral direction may be at least a factor of two, or a factor of three, or a factor of five, or even larger than the length of the second trench electrode along the first lateral direction. The length of first trench electrode may be set depending on a voltage blocking requirements of the semiconductor device. For example the length of the second trench electrode may range from 0.5 µm to 10 µm, or from 1.0 µm to 8 µm.

For example, the semiconductor device may further comprise a body region. A vertical distance between a bottom of the body region and the first main surface may be greater than a vertical distance between a bottom of the second trench segment and the first main surface. For example, the body region may adjoin a sidewall and/or a bottom side of the second trench segment and may include a channel region being a part of a body region that adjoins to the sidewall and/or to the bottom side of the second trench segment. In the channel region, a conductivity may be controlled via a voltage applied to the gate electrode. For example, a conductivity in the channel region may be switched between an on- and off-state by field effect controlled via the gate electrode. Conductivity types of the body region and the source region may differ from one another. For example, the body region may be p-doped and the source region may be n-doped, e.g. in case of an n-channel MOSFET. As an alternative, the body region may be n-doped and the source region may be p-doped, e.g. in case of a p-channel MOSFET.

For example, the drain may include a second trench and a first conductive material in the second trench. The first conductive material may be electrically coupled to the semiconductor body through at least a sidewall of the second trench. The first conductive material may be a highly doped semiconductor material, e.g. highly doped polycrystalline material. As an alternative or in addition, the first conductive material may be a metal. The first conductive material may be electrically coupled to the semiconductor body via a drain contact region. The drain contact region as part of the drain may be a highly doped region adjoining to the at least one sidewall of the second trench. For example, the drain contact region may an n⁺-doped region for providing an ohmic contact between a drift region of an n-channel MOSFET and the drain, for example.

For example, the source may include a third trench and a second conductive material in the third trench. The second conductive material may be electrically coupled to the semiconductor body through at least a sidewall of the third trench. Similar to the first conductive material in the second trench, the second conductive material may be a highly doped semiconductor material, e.g. highly doped polycrystalline material. As an alternative or in addition, the second conductive material may be a metal. The second conductive material may be electrically coupled to a source region. The source may include a highly doped source region adjoining to the at least one sidewall of the third trench. For example, the source region may an n⁺-doped region of an n-channel MOSFET, for example. In addition to the source region, the second conductive material may also be electrically coupled to a body contact region. The body contact region may also adjoin to the sidewall of the third trench, e.g. in a sidewall part that differs from a sidewall part where the source region adjoins to the third trench. The body contact region and the source region may differ in conductivity type. For an n-channel MOSFET, the body contact region may be a p⁺-doped region and the source region may be an n⁺-doped region, for example. For a p-channel MOSFET, the conductivity types of the body contact region and the source region are interchanged compared with the n-channel MOSFET. In some other examples, the source region and the body contact region may also adjoin to differently oriented surface parts, e.g. opposite sidewalls or sidewall and bottom side, of one trench, e.g. the third trench, or may adjoin to separate trenches, for example.

Structural and/or functional details described above for features, e.g. the source, or the drain, or the trench, or the first and second trench segments, or the first and second trench dielectrics, or the first and second trench electrodes, likewise apply to corresponding features described below with respect to the method of manufacturing a semiconductor device or the figures.

An example of the present disclosure relates to a method of manufacturing a semiconductor device. The method may include providing a semiconductor body having a first main surface and a second main surface opposite to the first main surface along a vertical direction. The method may further include forming a source and a drain. The method may further include forming a trench arranged between the drain and the source along a first lateral direction. The trench may include a first trench segment and a second trench segment merged into one another along the first lateral direction. The method may further include forming a first trench dielectric and a first trench electrode in the first trench segment. The method may further include forming a second trench dielectric and a second trench electrode in the second trench segment. The second trench electrode may be spaced from the first trench electrode along the first lateral direction.

For example, the first trench electrode and the second trench electrode may be concurrently formed. For example, the first trench electrode and the second trench electrode may be concurrently formed by a layer deposition process filling the first and second trench segments with a conductive material, e.g. highly doped polycrystalline silicon and/or metal.

For example, the second trench segment may be formed after forming the first trench segment. For example, the first segment may be covered by a mask, e.g. a hard mask, when forming the second trench segment by one or more etch processes. When forming the second trench segment, the first trench segment may already be at least partly filled with a material. For example, the first trench dielectric may already be formed in the first trench segment before forming the second trench segment. For example, the first trench electrode may not yet be formed in the first trench segment when forming the second trench segment. In some other examples, also the first trench electrode may already be formed in the first trench segment before forming the second trench segment. In some other examples, neither the first trench dielectric nor the first trench electrode is formed in the first trench segment before forming the second trench segment.

For example, forming the second trench segment may include removing part of the first trench dielectric. For example, when forming the first trench dielectric in the first trench segment, the first trench dielectric may also be formed over the first main surface. When forming the second trench segment, the first trench dielectric may be removed, e.g. by one or more etch processes, in a region where the second trench segment is to be formed.

For example, the method may further include forming a body region in the semiconductor body before forming the second trench segment. For example, the body region may be formed by one or more masked ion implantation processes and/or by one or more diffusion processes for introducing dopants into the semiconductor body.

The aspects and features mentioned and described together with one or more of the previously described examples and figures, may as well be combined with one or more of the other examples in order to replace a like feature of the other example or in order to additionally introduce the feature to the other example.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub–acts, -functions, -processes, -operations or –steps, respectively. Such sub acts may be included and part of the disclosure of this single act unless explicitly excluded.

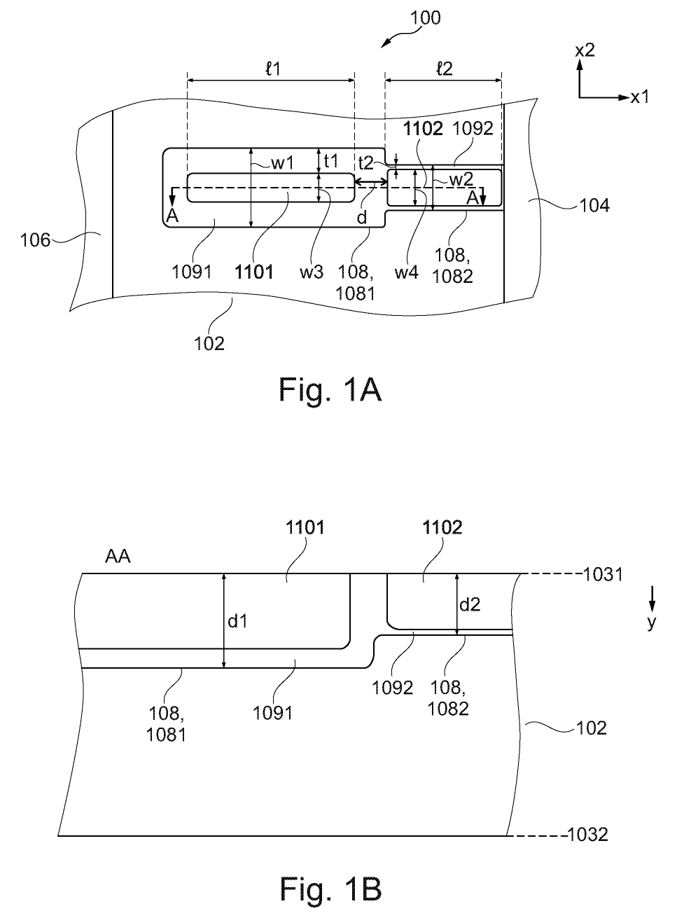

Referring to the schematic top view of FIG. 1A and the schematic cross-sectional view of FIG. 1B, a semiconductor device 100 according to an example is illustrated. In the illustrated example, the semiconductor device 100 is a lateral channel MOSFET. The semiconductor device 100 includes a semiconductor body 102 having a first main surface 1031 and a second main surface 1032 opposite to the first main surface 1031 along a vertical direction y. The semiconductor device 100 includes a source 104 and a drain 106. The semiconductor device 100 further includes a trench 108 arranged between the drain 106 and the source 104 along a first lateral direction x1. The trench 108 includes a first trench segment 1081 and a second trench segment 1082 merged into one another along the first lateral direction x1. A first trench dielectric 1091 and a first trench electrode 1101 are arranged in the first trench segment 1081. A second trench dielectric 1092 and a second trench electrode 1102 are arranged in the second trench segment 1082. The second trench electrode 1102 is spaced from the first trench electrode 1101 along the first lateral direction x1.

In the example illustrated in FIGS. 1A and 1B, the second trench electrode 1102 is a gate electrode and the second trench dielectric 1092 is a gate dielectric. A first vertical distance d1 between a bottom of the first trench segment 1081 and the first main surface 1031 is greater than a second vertical distance d2 between a bottom of the second trench segment 1082 and the first main surface 1031. In some other examples, the first and second vertical distances may also satisfy d1=d2 or d2>d1, for example.

In the example illustrated in FIGS. 1A and 1B, a width w1 of the first trench segment 1081 along a second lateral direction x2 is greater than a width w2 of the second trench segment 1082. The second lateral direction x2is perpendicular to the first lateral direction x1. A thickness t1 of the first trench dielectric 1091 is greater than a thickness t2 of the second trench dielectric 1092. A distance d between the first trench electrode 1101 and the second trench electrode 1102 along the first lateral direction x1is equal to or greater than the thickness t1 of the first trench dielectric 1091. A width w3of the first trench electrode 1101 is smaller than a width w4 of the second trench electrode 1102. A length l1of the first trench electrode 1101 along the first lateral direction x1 is greater than a length l2of the second trench electrode 1102 along the first lateral direction x1.

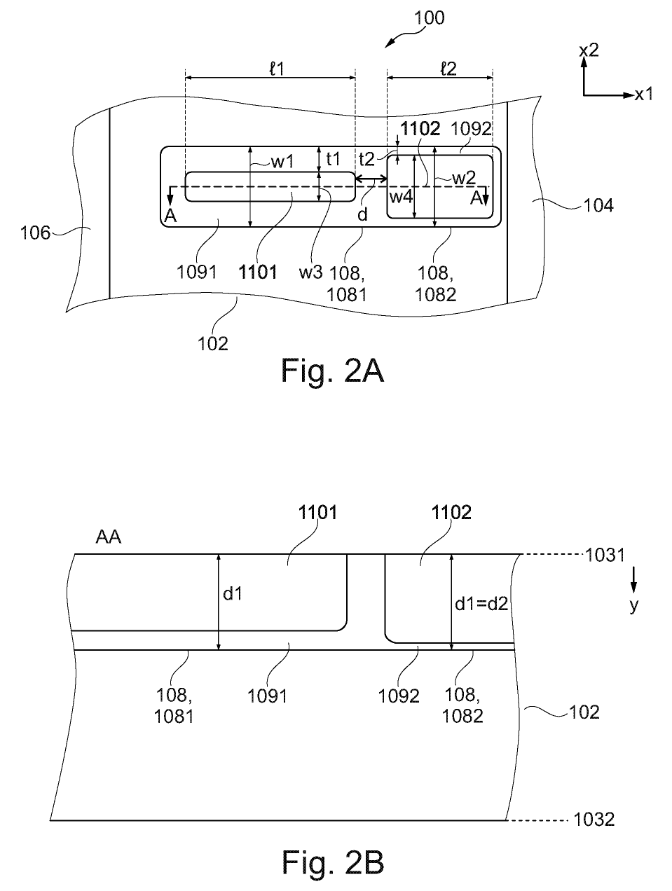

According to a further example illustrated in the schematic top and cross-sectional views of FIGS. 2A and 2B, a width w1 of the first trench segment 1081 along the second lateral direction x2 is equal to or almost equal to the width w2 of the second trench segment 1082, i.e. w1=w2 or w1≈w2. Likewise, the first vertical distance d1 between a bottom of the first trench segment 1081 and the first main surface 1031 is equal to or almost equal to a second vertical distance d2 between a bottom of the second trench segment 1082 and the first main surface 1031. The pairwise relations between d1, d2, and between l1, l2, and between w1, w2 may be altered with respect to the specific examples provided above so that all combinations are covered.

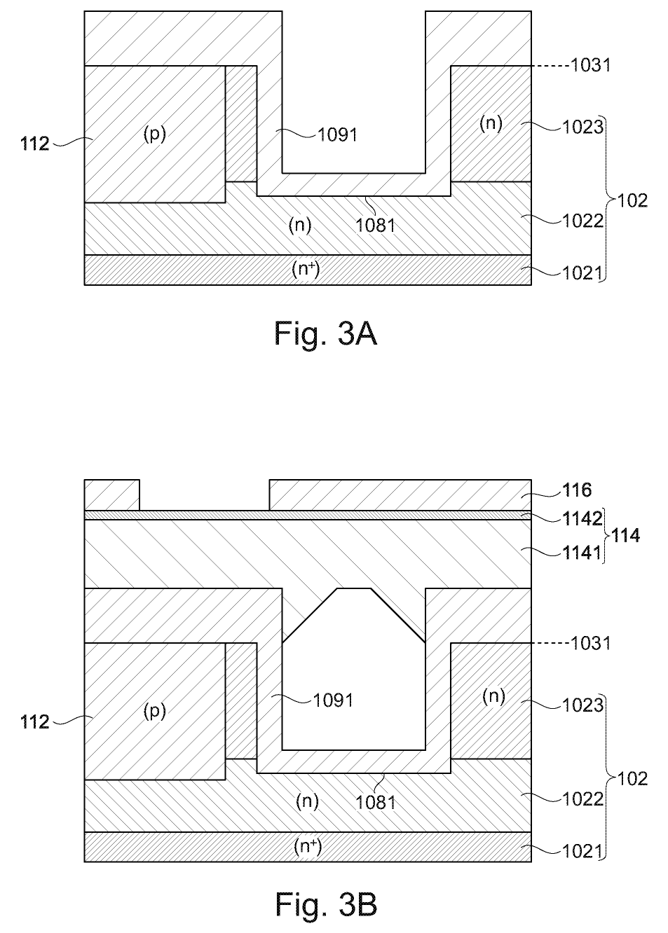

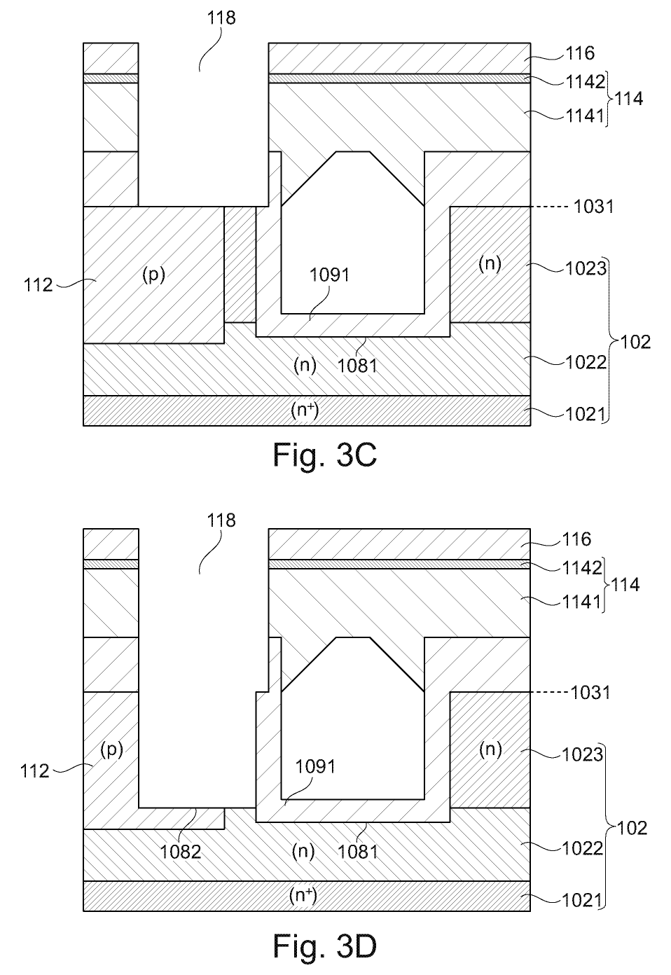

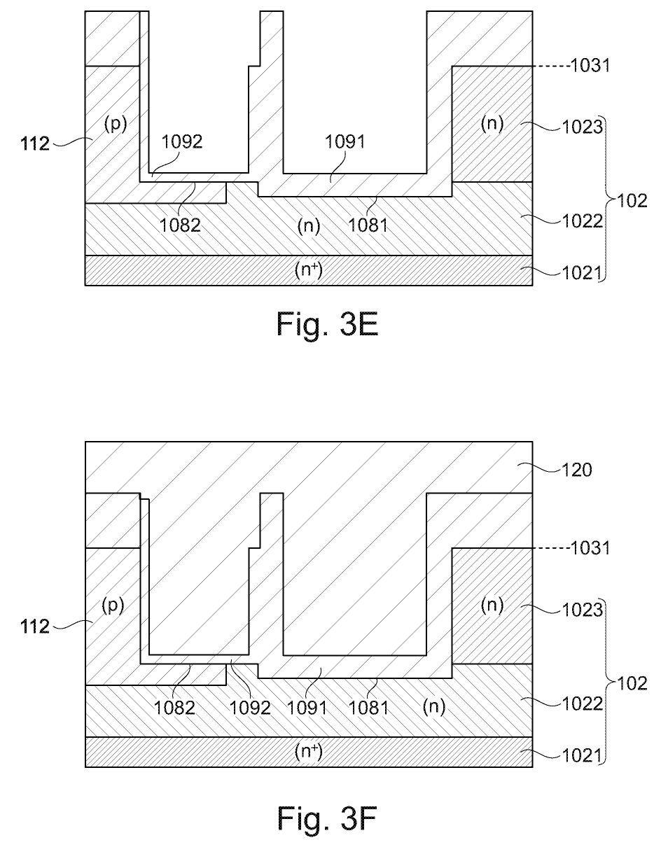

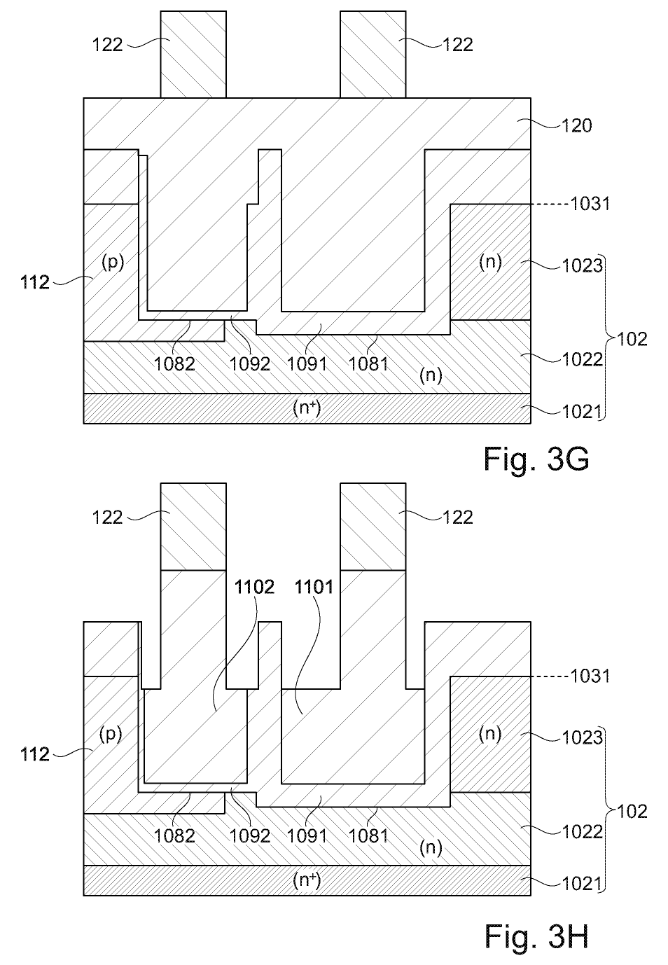

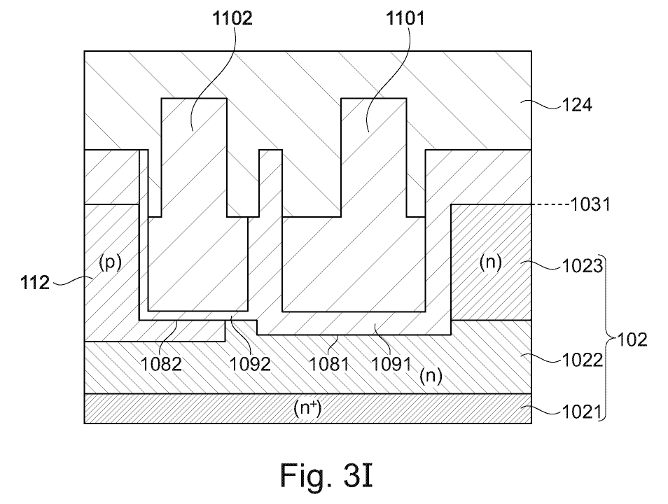

Referring to the schematic cross-sectional views of FIGS. 3A to 3I, an example of a method of manufacturing a semiconductor device is illustrated.

Referring to the schematic cross-sectional view of FIG. 3A, a semiconductor body 102 is provided. The semiconductor body includes an n⁺-doped substrate 1021, a first n-doped semiconductor layer 1022 on the semiconductor substrate 1022, and a second n-doped semiconductor layer 1022 on the first semiconductor layer 1021. The first and second semiconductor layers 1022, 1023 may be formed by an epitaxial layer deposition process, e.g. by a chemical vapor deposition (CVD) process. For example, a doping concentration in the second semiconductor layer 1023 may be larger than a doping concentration in the first semiconductor layer 1022. For example, a doping concentration in the first semiconductor layer may range from 5x10¹⁴ to 5x10¹⁶, and a doping concentration in the second semiconductor layer 1023 may range from 5x10¹⁵ to 1x10¹⁸. Moreover, a vertical extent in the first semiconductor layer 1022 may range from 2µm to 10µm, and a vertical extent in the second semiconductor layer 1023 may range from 1µm to 100µm, or from 2µm to 50µm.

In some other examples, a number of semiconductor layers over the semiconductor substrate 1021 may differ from two, and may be equal to one, three, four or may be even larger.

A first trench segment 1081 is formed in the semiconductor body 102 from a first main surface 1031 of the semiconductor body 102, e.g. by one or more masked etch processes. A first trench dielectric 1091 is formed in the first trench segment 1081, wherein the first trench dielectric 1091 lines sidewalls and a bottom side of the first trench segment 1081. The first trench dielectric 1091 may also be formed over the first main surface 1031. The first trench dielectric 1091 may include one or more dielectric materials, e.g. oxides, nitrides, high-k-dielectrics, low-k-dielectrics. A bottom side of the first trench dielectric 1091 may be located below a top side of the first semiconductor layer 1022, for example. A p-doped body region 112 is formed in the semiconductor body 102 by a masked ion implantation process and/or diffusion process from a diffusion source.

Referring to the schematic cross-sectional view of FIG. 3B, a cover structure 114 is formed over the first main surface 1031 covering the first trench segment 1081. For example, the cover structure 114 may include one or more cover layers, e.g. a first cover layer 1141 suitable for covering the first trench segment, e.g. carbon formed by lateral overgrowth, and a second cover layer 1141 suitable for providing a desired etch selectivity for subsequent etch process(es), e.g. amorphous silicon, a-Si. A mask 116, e.g. a resist mask, is formed over the cover structure 114.

Referring to the schematic cross-sectional view of FIG. 3C, an opening 118 is formed in the cover structure 114 and the first trench dielectric 1091 over the first main surface 1031 by using the mask 116.

Referring to the schematic cross-sectional view of FIG. 3D, the opening 118 in the cover structure 114 and the first trench dielectric 1091 is extended into the semiconductor body 102 for forming the second trench segment 1082, e.g. by one or more etch processes using the mask 116 as an etch mask.

Referring to the schematic cross-sectional view of FIG. 3E, the mask 116 and the cover structure 114 are removed and the second trench dielectric 1192 is formed in the second trench segment 1082. The second trench dielectric 1092 lines sidewalls and a bottom side of the second trench segment 1082. The second trench dielectric 1092 may include one or more dielectric materials, e.g. oxides, nitrides, high-k-dielectrics, low-k-dielectrics.

Referring to the schematic cross-sectional view of FIG. 3F, an electrode material 120, e.g. doped polycrystalline silicon or a combination of conductive materials, is formed in the first and second trench segments 1081, 1082.

Referring to the schematic cross-sectional view of FIG. 3G, a second mask 122 is formed over the electrode material 120 for covering those parts of the electrode material 120 where the first and second trench electrodes are defined in subsequent processes.

Referring to the schematic cross-sectional view of FIG. 3H, the electrode material 120 is patterned, e.g. by one or more etch processes, for defining the first trench electrode 1101 and the second trench electrode 1102.

Referring to the schematic cross-sectional view of FIG. 3I, a cap dielectric 124 is formed over the first and second trench electrodes 1101, 1102.

In addition to the process features illustrated in the schematic cross-sectional views of FIGS. 3A to 3I, further processes may be carried out for forming the semiconductor device. Some of the additional processes may be carried out before the processes illustrated in FIGS. 3A to 3I. Some other processes may be carried out after the processes illustrated in FIGS. 3A to 3I. Yet other processes may be carried out together with or between processes illustrated in FIGS. 3A to 3I. For example, the further process features may include, inter alia, chemical mechanical polishing, CMP, forming source, drain, load and control contacts such as source pad, drain pad, gate pad, for example.

The aspects and features mentioned and described together with one or more of the previously detailed examples and figures, may as well be combined with one or more of the other examples in order to replace a like feature of the other example or in order to additionally introduce the feature to the other example.

What is claimed is:

1. A semiconductor device, comprising:
a semiconductor body having a first main surface and a second main surface opposite to the first main surface along a vertical direction;
a source;
a drain;
a trench arranged between the drain and the source along a first lateral direction, wherein the trench includes a first trench segment and a second trench segment merged into one another along the first lateral direction;
a first trench dielectric and a first trench electrode in the first trench segment;
a second trench dielectric and a second trench electrode in the second trench segment, wherein the second trench electrode is spaced from the first trench electrode along the first lateral direction.

2. The semiconductor device of claim 1, wherein the second trench electrode is a gate electrode and the second trench dielectric is a gate dielectric.

3. The semiconductor device of claim 1, wherein a first vertical distance between a bottom of the first trench segment and the first main surface is greater than a second vertical distance between a bottom of the second trench segment and the first main surface.

4. The semiconductor device of claim 1, wherein a width of the first trench segment along a second lateral direction is greater than a width of the second trench segment, and wherein the second lateral direction is perpendicular to the first lateral direction.

5. The semiconductor device of claim 1, wherein a thickness of the first trench dielectric is greater than a thickness of the second trench dielectric.

6. The semiconductor device of claim 5, wherein a distance between the first trench electrode and the second trench electrode along the first lateral direction is equal to or greater than the thickness of the first trench dielectric.

7. The semiconductor device of claim 1, wherein a width of the first trench electrode is smaller than a width of the second trench electrode.

8. The semiconductor device of claim 1, wherein a length of the first trench electrode along the first lateral direction is greater than a length of the second trench electrode along the first lateral direction.

9. The semiconductor device of claim 1, further comprising:
a body region,
wherein a vertical distance between a bottom of the body region and the first main surface is greater than a vertical distance between a bottom of the second trench segment and the first main surface.

10. The semiconductor device of claim 1, wherein the drain includes a second trench and a first conductive material in the second trench, the first conductive material being electrically coupled to the semiconductor body through at least a sidewall of the second trench.

11. The semiconductor device of claim 1, wherein the source includes a third trench and a second conductive material in the third trench, the second conductive material being electrically coupled to the semiconductor body through at least a sidewall of the third trench.

12. A method of manufacturing a semiconductor device, the method comprising:
providing a semiconductor body having a first main surface and a second main surface opposite to the first main surface along a vertical direction;
forming a source and a drain;
forming a trench arranged between the drain and the source along a first lateral direction, wherein the trench includes a first trench segment and a second trench segment merged into one another along the first lateral direction;
forming a first trench dielectric and a first trench electrode in the first trench segment; and
forming a second trench dielectric and a second trench electrode in the second trench segment, wherein the second trench electrode is spaced from the first trench electrode along the first lateral direction.

13. The method of claim 12, wherein the first trench electrode and the second trench electrode are concurrently formed.

14. The method of claim 12, wherein the second trench segment is formed after forming the first trench segment.

15. The method of claim 12, wherein forming the second trench segment comprises:
removing part of the first trench dielectric.

16. The method of claim 12, further comprising:
forming a body region in the semiconductor body before forming the second trench segment.

17. The method of claim 16, wherein a vertical distance between a bottom of the body region and the first main surface is greater than a vertical distance between a bottom of the second trench segment and the first main surface.

18. The method of claim 12, wherein forming the second trench segment comprises:
forming a cover structure over the first main surface, the cover structure covering the first trench segment;
forming an opening in the cover structure and the first trench dielectric over the first main surface; and
extending the opening in the cover structure and the first trench dielectric into the semiconductor body.

19. The method of claim 18, wherein the cover structure comprises a first cover layer suitable for covering the first trench segment and a second cover layer suitable for providing a desired etch selectivity for one or more subsequent etch processes.

20. The method of claim 19, wherein the first cover layer comprises carbon formed by lateral overgrowth, and wherein the second cover layer comprises amorphous silicon.
